(19) United States
(12) Patent Application Publication
(10) Pub. No.: US 2014/0332934 A1
(43) Pub. Date: Nov. 13, 2014

(54) SUBSTRATES FOR SEMICONDUCTOR DEVICES

(71) Applicant: Element Six Limited, London (GB)

(72) Inventors: Timothy Peter Mollart, Oxfordshire (GB); Quanzhong Jiang, Bath (GB); Christopher Rhys Bowen, Bath (GB); Duncan William Edward Allsopp, Bath (GB); Michael John Edwards, Bath (GB)

(21) Appl. No.: 14/362,839

(22) PCT Filed: Dec. 12, 2012
(86) PCT No.: PCT/EP2012/075250

§ 371 Date: Jun. 4, 2014

Related U.S. Application Data
(60) Provisional application No. 61/576,605, filed on Dec. 16, 2011.

(30) Foreign Application Priority Data
Dec. 16, 2011 (GB) 1121655.3

(51) Int. Cl. C30B 25/18; H01L 23/373; H01L 21/02; H01L 21/311; H01L 29/06

(52) U.S. Cl. CPC C30B 25/186; H01L 21/311; H01L 21/31111; H01L 29/0649; H01L 21/31122; H01L 21/02115; H01L 23/3732
USPC 257/629; 438/759; 438/694; 117/95

(57) ABSTRACT

A method of manufacturing a composite substrate for a semiconductor device, the method comprising: selecting a substrate wafer comprising: a first layer of single crystal material suitable for epitaxial growth of a compound semiconductor thereon and having a thickness of 100 μm or less;a second layer having a thickness of no less than 0.5 μm and formed of a material having a lower thermal expansion coefficient than the first layer of single crystal material and/or is formed of a material which has a higher fracture strength than that of the first layer of single crystal material; and a third layer forming a handling wafer on which the first and second layers are disposed, wherein the substrate wafer has an aspect ratio, defined by a ratio of thickness to width, of no less than 0.25/100; growing a first polycrystalline CVD diamond layer on the first layer of single crystal material using a chemical vapour deposition technique to form a composite comprising the substrate wafer bonded to the polycrystalline diamond layer via the first layer of single crystal material, wherein during growth of the first polycrystalline CVD diamond layer a temperature difference at a growth surface between an edge and a centre point thereof is maintained to be no more than 80° C.; and removing the second and third layers of the substrate wafer to form a composite substrate comprising the polycrystalline diamond layer directly bonded to the first layer of single crystal material.

### FIELD OF INVENTION

The present invention relates to the manufacture of substrates for semiconductor devices.

### BACKGROUND OF INVENTION

Optoelectronic, high power, and high frequency devices are increasingly being fabricated using wide band gap compound semiconductor materials such as gallium nitride, aluminium nitride, and silicon carbide. Such semiconductor materials are frequently grown heteroepitaxially in thin film form onto a suitable substrate which provides a template for crystal growth. Typical substrates include sapphire, silicon carbide, and silicon. For semiconductor devices such as microwave amplifier circuits, the substrate should be electrically insulating for the device to function.

A well known problem in semiconductor devices is that of heat dissipation. High temperatures often limit the performance and/or lifetime of such devices. This is a particular problem in semiconductor devices which operate at high power and/or high frequency such as microwave amplifiers, power switches and optoelectronic devices. It is therefore desirable to be able to spread any heat generated by component devices to reduce temperatures and thus improve device performance, increase device lifetime, and/or increase power density. Accordingly, it is desirable to utilize a substrate material with a high thermal conductivity to spread the heat generated by a device, lowering the power density and facilitating dissipation via a heat sink thus improving device performance, increasing lifetime, and/or enabling an increase in power density.

Diamond has unique properties as a heat spreading material, combining the highest room temperature thermal conductivity of any material, with high electrical resistivity and low dielectric loss when in an intrinsic undoped form. Thus diamond is utilized as a heat spreading substrate for semiconductor components in a number of high power density applications. The advent of large area polycrystalline diamond produced by a chemical vapour deposition (CVD) technique has expanded the applications for diamond heat spreaders via an increase in area and a reduction in cost. The majority of favourable thermal, dielectric and insulating properties of diamond are not dependent on the single crystal structure of naturally occurring or synthetic single crystal diamond material. Accordingly, polycrystalline CVD diamond wafers have been developed and are commercially available in sizes that enable them to be directly integrated with the fabrication processes of wide band gap semiconductors as a substrate material.

In light of the above, it is evident that for thin film compound semiconductor materials, an ability to integrate diamond as a carrier substrate could greatly improve thermal performance. For high power devices, the challenge is to position an active region of a device in as close proximity as possible to the heat spreading diamond substrate, since any intermediate carrier substrate material such as sapphire, silicon, or silicon carbide acts as a thermal barrier.

Compound semiconductor materials can be grown directly on a polycrystalline diamond substrate using, for example, a metal organic vapour phase epitaxy (MOVPE) technique. However, semiconductor material grown in such a manner will itself be polycrystalline, the crystals being distributed over a range of crystallographic orientations relative to the plane of the substrate. Such a polycrystalline layer of semiconductor material will tend to have relatively low charge mobility and thus will not provide good device performance for many proposed applications, particularly those which require high charge (electron and/or hole) mobility characteristics such as a high electron mobility transistor (HEMT) used in microwave frequency amplifier circuits. As such, it is desirable to provide a method which allows the formation of a monocrystalline semiconductor layer.

U.S. Pat. No. 7,595,507 and US 2010/0001293 disclose methods of forming semiconductor device substrates which comprise growing diamond over a monocrystalline silicon carbide layer. US 2009/0272984 also discloses a method of forming a semiconductor device substrate comprising diamond and silicon carbide. Such composite diamond-silicon carbide substrates can be used to form semiconductor devices. When forming such devices, the mono-crystalline silicon carbide layer can be used to grow a monocrystalline semiconductor layer thereover.

US 2006/0113545 discloses substrate structures comprising silicon-diamond-silicon multilayer structures. One problem with using silicon is that it offers relatively poor thermal and resistivity properties compared to silicon carbide. As such, it is desirable to make the silicon layer very thin such that the polycrystalline diamond will be disposed close to the active semiconductor components to effectively dissipate heat generated during operation.

Various prior art documents disclose methods of growing polycrystalline diamond on a substrate, reducing the thickness of the substrate to form a thin single crystal layer disposed on the polycrystalline diamond, and then growing active semiconductor layers on the thin single crystal layer. Examples of such prior art documents are briefly discussed below.

WO 2005/122284 and WO 2006/100559 disclose growth of polycrystalline diamond material on a silicon wafer followed by thinning of the silicon wafer by grinding or lapping to achieve a thin layer of silicon disposed on the polycrystalline diamond material.

EP0442304 discloses growth of polycrystalline diamond material on a silicon wafer. It is described that a thin layer of single crystal silicon carbide forms at an interface between the silicon and diamond material during growth. The document suggests that the silicon wafer can be removed to leave the thin layer of silicon carbide adhered to the polycrystalline diamond material and this thin layer of silicon carbide can be used as a growth surface for fabrication of semiconductor layers. The present inventors consider that this is incorrect as they have found that while a thin layer of silicon carbide does form at the interface between the silicon and diamond materials, this layer is amorphous and found the latter not suitable for fabricating single crystal semiconductor materials thereon by epitaxial growth.

WO2005/074013 and US 2009/0272984 disclose ion implanting a buried SiO₂ layer into a silicon carbide wafer, growing polycrystalline diamond material on the wafer, and then removing the bulk of the silicon carbide wafer by using the implanted SiO₂ layer as a release layer.

U.S. Pat. No. 7,595,507 discloses ion implanting a buried SiO₂ layer of 100 nm to 200 nm thickness into a silicon wafer, growing polycrystalline diamond material on the wafer, and then removing the bulk of the silicon wafer using a wet etch with the thin buried SiO₂ layer acting as an etch stop to achieve a thin layer of silicon disposed on the polycrystalline diamond material.

U.S. Pat. No. 7,695,564 discloses a similar method which comprises ion-implantation of oxygen into a silicon wafer to form a wafer comprising a bulk silicon wafer layer of an unspecified thickness, a buried oxide layer having a thickness of approximately 100-200 nm, and a silicon overlay structure having a thickness of 50-500 nm. A polycrystalline diamond film of approximately 200 to 1500 micrometers is grown on the silicon overlayer. The bulk silicon wafer layer and the buried oxide layer are then removed to leave a composite structure comprising the polycrystalline diamond film and the silicon overlayer. A number of different methods are described for removing the silicon to form a diamond substrate with a thin silicon overlayer including: (1) selectively dissolving the buried oxide layer; (2) wet etching the bulk silicon layer followed by wet etching of the buried oxide layer; (3) lapping and polishing the bulk silicon layer followed by wet etching; or (4) lapping and polishing the bulk silicon layer followed by dry etching. The finished silicon-on-diamond substrate consists of an approximately 50 to 200 nm thick monocrystalline silicon film which is epitaxially fused to an approximately 300 to 1500 micrometer thick polycrystalline diamond substrate.

While it would seem to be simple in principle to apply any of the aforementioned techniques to thin down a substrate wafer after polycrystalline diamond growth thereon to achieve a polycrystalline diamond wafer with a thin layer of the substrate wafer adhered thereto, in practice a problem exists with known prior art techniques. Namely, as the substrate wafer is thinned down cracking occurs in the thin layer such that although a thin layer is achieved is not of high quality. This is problematic because the quality of the thin layer will affect the quality of the semiconductor layers epitaxially grown thereover to form an electronic device and this detrimentally affects device performance. In particular, the present inventors have found that as the single crystal layer adhered to the polycrystalline diamond material is thinned to a depth of less than 100 μm cracks begin to form in the thin layer of single crystal material. While it was initially thought that such cracking may be a result of mechanical damage caused by grinding, lapping, and polishing techniques, it has been found that this same problem occurs when using etching techniques such as those described above.

It is an aim of certain embodiments of the present invention to solve the aforementioned problem and provide a method of fabricating a high quality thin layer of single crystal material on a polycrystalline diamond carrier. Such a composite substrate can be used to fabricate higher quality single crystal semiconductor layers thereon and thus fabricate a device with better performance characteristics.

### SUMMARY OF INVENTION

According to a first aspect of the present invention there is provided a method of manufacturing a composite substrate for a semiconductor device, the method comprising:
selecting a substrate wafer comprising: a first layer of single crystal material suitable for epitaxial growth of a compound semiconductor thereon and having a thickness of 100 μm or less; a second layer having a thickness of no less than 0.5 μm and formed of a material having a lower thermal expansion coefficient than the first layer of single crystal material and/or is formed of a material which has a higher fracture strength than that of the first layer of single crystal material; and a third layer forming a handling wafer on which the first and second layers are disposed, wherein the substrate wafer has an aspect ratio, defined by a ratio of thickness to width, of no less than 0.25/100;
growing a first polycrystalline CVD diamond layer on the first layer of single crystal material using a chemical vapour deposition technique to form a composite comprising the substrate wafer bonded to the polycrystalline diamond layer via the first layer of single crystal material, wherein during growth of the first polycrystalline CVD diamond layer a temperature difference at a growth surface between an edge and a centre point thereof is maintained to be no more than 80° C.; and
removing the second and third layers of the substrate wafer to form a composite substrate comprising the polycrystalline diamond layer directly bonded to the first layer of single crystal material.

Accordingly to a second aspect of the present invention there is provided a composite substrate for a semiconductor device, the composite substrate comprising:
a layer of polycrystalline diamond; and
a layer of single crystal material suitable for epitaxial growth of a compound semiconductor,
wherein the layer of single crystal material is directly bonded to the layer of polycrystalline diamond and has a thickness of 100 μm or less,
wherein the layer of single crystal material is substantially crack free over at least a central region thereof, wherein the central region is at least 50%, 60% 70%, 80%, 90%, or 95% of a total area of layer of single crystal material, and wherein the central region has no cracks which extend greater than 2 mm in length.

Accordingly to a third aspect of the present invention there is provided a method of manufacturing a semiconductor device comprising:
providing the composite substrate as described above; and
epitaxially growing a layer of single crystal compound semiconductor material over the layer of single crystal material.

Accordingly to a fourth aspect of the present invention there is provided a semiconductor device comprising:
the composite substrate as described above; and
a layer of single crystal compound semiconductor material epitaxially grown over the layer of single crystal material,
wherein the layer of single crystal compound semiconductor material has a charge mobility no less than 1000 cm²V⁻¹s⁻¹, 1200 cm²V⁻¹s⁻¹, 1400 cm²V⁻¹s⁻¹, 1600 cm²V⁻¹s⁻¹, 1800 cm²V⁻¹s⁻¹, or 2000 cm²V⁻¹s⁻¹.

### BRIEF DESCRIPTION OF THE DRAWINGS

For a better understanding of the present invention and to show how the same may be carried into effect, embodiments of the present invention will now be described by way of example only with reference to the accompanying drawings, in which:

FIGS. 1(a) and 1(b) illustrate a prior art method of fabricating a thin silicon-on-diamond composite substrate;

FIGS. 2(a) to 2(c) illustrate a method of fabricating a thin silicon-on-diamond composite substrate according to an embodiment of the present invention; and

FIG. 3 illustrates a composite substrate comprising a compound semiconductor layer disposed thereon.

### DETAILED DESCRIPTION OF CERTAIN EMBODIMENTS

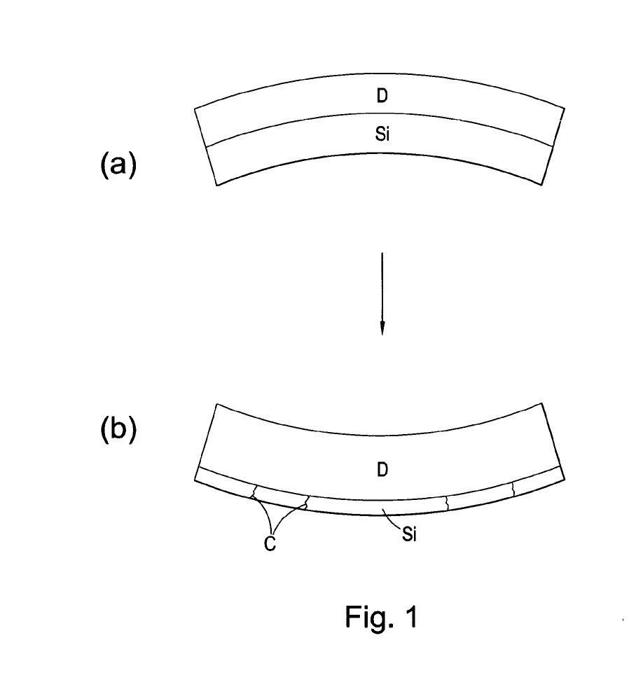

The present inventors believe that the aforementioned problem of cracking of the single crystal diamond material as the material is thinned to less than 100 μm is a result of thermally induced stress generated by the CVD diamond growth process and caused by a mismatch in thermal expansion coefficient between the polycrystalline diamond material and the single crystal wafer material. For example, silicon has a much higher thermal expansion coefficient than diamond (at least at temperatures below about 700° C.) such that on cooling after CVD diamond growth the silicon wafer Si contracts more than the polycrystalline diamond D causing bowing as illustrated in FIG. 1(a). During processing to thin the silicon wafer the stress in the silicon increases and as the layer of silicon reaches a thickness of approximately 100 μm the composite tends to flip to bow the other way such that the thin silicon layer Si is placed in tension as illustrated in FIG. 1(b). This tension tends to cause the thin silicon layer to crack C.

The aforementioned problem can be partially addressed by controlling the temperature of the growth surface of the polycrystalline CVD diamond layer during growth such that a temperature difference at a growth surface between an edge and a centre point thereof is maintained to be no more than 80° C., 60° C., 40° C., 20° C., 10° C., 5° C., or 1° C. Such temperature control can aid in alleviate problems of thermally induced stresses leading to cracking.

The present inventors have also found that the mechanical stiffness of the substrate wafer must be sufficiently large to alleviate the problem of bowing and cracking of the silicon material during processing of the substrate wafer after CVD diamond growth thereon. The present inventors have found that the required level of mechanical stiffness can be achieved by providing a substrate wafer which is relatively thick (compared with its lateral width). Otherwise, even if the temperature across the growth surface is controlled to vary by no more than 80° C., plastic deformation of the substrate wafer still occurs. For example, the aspect ratio of the substrate wafer, defined by a ratio of thickness to width, should be no less than 0.25/100, 0.30/100, 0.40/100, 0.50/100, 0.60/100, 0.70/100, 0.80/100, 0.90/100, or 1.0/100. However, if the substrate wafer becomes too thick then this adds significant expense. As such, in practice the substrate wafer has an aspect ratio no more than 10/100, 8/100, 6/100, 4/100, or 2/100.

Despite the above modifications, cracking of the thin silicon layer of material during thinning of the substrate wafer can still be problematic. The present inventors have found that the thin silicon layer can be made more resistant to cracking under the tensioning mechanism illustrated in FIG. 1(b) if a relatively thick layer of SiO₂ is introduced into the silicon wafer prior to CVD diamond growth thereon. While not being bound by theory it is postulated that this reduction in cracking may be due to the relatively thick SiO₂ layer functioning as a crack stop and/or the relatively thick SiO₂ layer functioning to pre-compress the thin overlying layer of single crystal silicon material during CVD diamond growth due to its lower thermal expansion coefficient such that it is more resistant to tensile stress induced during processing of the silicon wafer to achieve a thin layer. In either case, it is important that the SiO₂ layer should have a thickness sufficient to fulfill either of these functions.

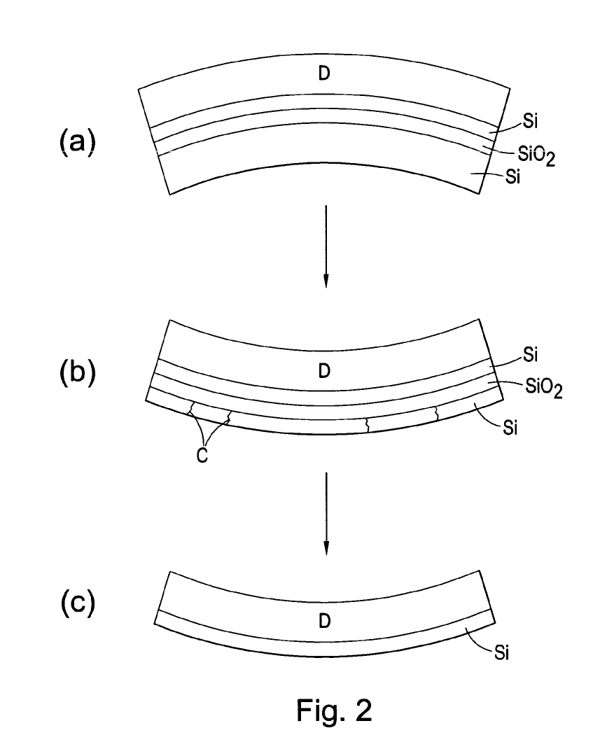

This is illustrated in FIG. 2. As shown in FIG. 2(a) bowing of the substrate after CVD diamond growth thereon can still occur as described previously. Furthermore, as described previously, during processing to thin the silicon wafer the stress in the silicon increases and as the layer of silicon reaches a thickness of approximately 100 μm the composite tends to flip to bow the other way such that the thin silicon layer Si is placed in tension as illustrated in FIG. 2(b). However, even if cracks C form in the silicon handle wafer these cracks are prevented from propagating into the thin silicon layer adjacent the CVD diamond material by the relatively thick SiO₂ layer. Further processing can remove the remaining silicon and the SiO₂ layer thus leaving a thin silicon layer adhered to the CVD diamond material without any significant cracking As illustrated in FIG. 2(c).

For example, if a very thin layer of SiO₂ is provided then this layer will not provide sufficient compression to the thin layer of single crystal material during CVD diamond growth and/or not provide a sufficient barrier to crack propagation into the thin layer of single crystal material adjacent the polycrystalline diamond layer during processing. Common ion implanted SiO₂ buried oxide layers are usually of the order of 100 to 200 nm. While such layers are sufficient to function as effective etch stops or release layers as described in the prior art, it is believed that such thin layers are insufficient to generate the pre-compression and/or crack stop functionality required to prevent cracking of the thin layer of single crystal material adjacent the polycrystalline diamond layer during processing due to the tension mechanism as described herein.

As such, it is believed that it is important to select a substrate wafer with a relatively thick layer of SiO₂ disposed adjacent to the thin layer of single crystal material adhered to the polycrystalline CVD diamond material. While such substrates are commercially available, known as silicon-on-insulator or SOI, substrates with thicker layers of SiO₂ are more expensive and thus only tend to be selected when it is considered that a thicker layer of SiO₂ is essential for a particular application. Furthermore, forming a thicker layer of buried SiO₂ generally requires a higher implantation dose leading to increased damage of the thin layer of silicon. As previously described, it is desirable to provide a high quality thin layer of silicon to grow better quality compound semiconductor layers thereon. Accordingly, it is counter-intuitive that selecting a silicon-on-insulator substrate with a relatively thick layer of SiO₂ would be beneficial to achieve this function as substrates with thicker layers of SiO₂ formed by ion implantation would tend to have a higher degree of implantation damage. In practice, if has been found that any decrease in the quality of the thin layer of silicon due to ion implantation damage is far outweighed by the benefits of alleviating cracking due to the tension mechanism as described herein.

In light of the above, it has been found to be advantageous to provide a substrate wafer comprising a silicon handling wafer, a relative thick layer of SiO₂, and a thin layer of silicon on which CVD diamond growth is performed.

Further to the above, the present inventors have realized that the pre-compression and/or crack stop mechanisms as described can be implemented using materials other than silicon and SiO₂. The key feature is the provision of a substrate wafer comprising: a thin layer of single crystal material; a carrier wafer; and a crack-stop layer disposed between the thin layer of single crystal material and the carrier wafer, the crack-stop layer being at least 0.5 μm thick and formed of a material which has a thermal expansion coefficient lower than that of the thin layer of single crystal material and/or formed of a material which has a higher fracture strength than that of the thin layer of single crystal material.

In light of the above, a first aspect of the present invention provides a method of manufacturing a composite substrate for a semiconductor device, the method comprising:
selecting a substrate wafer comprising: a first layer of single crystal material suitable for epitaxial growth of a compound semiconductor thereon and having a thickness of 100 μm or less; a second layer having a thickness of no less than 0.5 μm and formed of a material having a lower thermal expansion coefficient than the first layer of single crystal material and/or is formed of a material which has a higher fracture strength than that of the first layer of single crystal material; and a third layer forming a handling wafer on which the first and second layers are disposed, wherein the substrate wafer has an aspect ratio, defined by a ratio of thickness to width, of no less than 0.25/100;
growing a first polycrystalline CVD diamond layer on the first layer of single crystal material using a chemical vapour deposition technique to form a composite comprising the substrate wafer bonded to the polycrystalline diamond layer via the first layer of single crystal material, wherein during growth of the first polycrystalline CVD diamond layer a temperature difference at a growth surface between an edge and a centre point thereof is maintained to be no more than 80° C.; and
removing the second and third layers of the substrate wafer to form a composite substrate comprising the polycrystalline diamond layer directly bonded to the first layer of single crystal material.

The first layer of single crystal material may have a thickness of: 75 μm or less; 50 μm or less; 30 μm or less; 20 μm or less; 10 μm or less; 5 μm or less; 3 μm or less; 2 μm or less; or 1 μm or less. Ideally this layer should be as thin as possible such that after growth of a compound semiconductor thereon the distance between the polycrystalline CVD diamond material and the compound semiconductor is minimized to ensure good heat dissipation. However, the layer must still provide a good quality single crystal growth surface to ensure good quality epitaxial growth of the compound semiconductor.

In relation to the above, it has been found to be advantageous to form the first layer of single crystal material to a thickness greater than 10 nm, 20 nm, 50 nm, 100 nm, 200 nm, or 500 nm. For example, if the single crystal material is silicon then the first 10 to 20 nm of silicon at the diamond interface tends to be amorphous silicon carbide formed during CVD diamond growth. As such, if the substrate wafer is processed to a depth less than 10 nm, the resultant film may be amorphous silicon carbide rather than single crystal silicon as desired. In this regard, it should be noted that when we refer to a silicon layer directly bonded to a CVD diamond layer, it will be understood that the interface between the silicon and the CVD diamond layer may comprise a very thin layer of amorphous silicon carbide formed during CVD diamond growth on the silicon.

The first layer of single crystal material should be formed of a material which is suitable for epitaxial growth of a compound semiconductor thereon. Examples include silicon, silicon carbide, or a nitride such as aluminium nitride. One possible arrangement utilizes a high electrical resistivity {111} oriented silicon material for this layer as this material can aid in preventing electrical shorting in a device structure while also providing a good growth surface for epitaxial growth of a compound semiconductor.

The second layer of material may have a thickness of: 0.75 μm or more; 1.0 μm or more; 2 μm or more; or 4 μm or more. The thickness of this layer must be sufficient to act as a suitable crack-stop and/or function to pre-compress the thin overlying layer of single crystal material. However, if the pre-compression mechanism is dominant then it is envisaged that thermal mismatches between the first and second layers could potentially increase the problem of cracking, for example during heat-up of the substrate wafer prior to CVD diamond growth thereon. The most preferable thickness for the second layer will to some extent depend on the particular combination of materials and layer thicknesses used for the various layers within the substrate wafer and the thickness of the CVD diamond layer grown thereon. However, it has been found that for certain combinations of materials such as silicon and SiO₂ a thickness of no more than 5 or 10 μm is sufficient.

To increase the effect of pre-compressing the first layer it may be advantageous to form the second layer of material using a material having a lower thermal expansion coefficient than the CVD synthetic diamond material. Alternatively, or additionally, to improve the second layers functionality as a crack-stop is can be advantageous to form the layer of an amorphous material. In this regard, it may be noted that SiO₂ can fulfill both these requirements.

As previously mentioned, in practice it can be convenient to provide a substrate wafer which further comprises a third layer forming a handling wafer on which the first and second layers are disposed. However, if such a handling wafer is provided then it must be appreciated that the handling wafer will itself contribute to stress within the first layer of single crystal material. That is, if the handing wafer is made too thick or too thin then thermally induced strain can lead to cracking of the first layer of single crystal material. As such, the handing wafer may have a thickness in a range: 0.3 mm to 2.0 mm; 0.3 mm to 1.8 mm; 0.3 mm to 1.5 mm; 0.3 mm to 1.3 mm; 0.3 mm to 1.0 mm; or 0.5 mm to 0.8 mm. Such thicknesses are suitable for a substrate wafer having a diameter in a range: 20 mm to 300 mm; 20 mm to 250 mm; 20 mm to 200 mm; 20 mm to 160 mm; 40 mm to 140 mm; 60 mm to 120 mm; 80 mm to 120 mm; or 90 mm to 110 mm.

The handling wafer will generally be formed of a material which has a thermal expansion coefficient larger than the material of the second layer and similar or the same as the first layer of single crystal material. Such a handling wafer may be formed of silicon, silicon carbide, or a nitride. The material of the handling wafer may have a different crystallographic orientation to the material of the first layer. For example, in one arrangement the handling wafer may be formed of {100} oriented silicon. This material is less expensive that the {111} oriented silicon material which is preferred for the first layer of single crystal material. The material of the handling wafer may also have a lower electrical resistivity than preferred materials used to fabricate the first layer, the preference for high electrical resistivity not being required for the handling wafer as it does not form part of the final device structure.

The above described substrate wafer structures are suitable for growing polycrystalline diamond to sufficient thickness for thermal substrate applications. For example, polycrystalline diamond grown to a thickness in the range: 25 μm to 150 μm 50 μm to 130 μm; 70 μm to 130 μm; 80 μm to 120 μm, or 90 μm to 110 μm. However, as the thickness of the polycrystalline diamond material is increased, thermal expansion coefficient mismatches can lead to the increased risk of cracking within the first layer of single crystal material of the substrate wafer during processing. As such, in one arrangement it can be advantageous to first grow a thin layer of CVD diamond material, process the substrate wafer to achieve a thin layer of single crystal material, and then proceed with a further CVD diamond growth step to increase the thickness of the CVD diamond material by growing a second layer of CVD diamond material over the first layer of CVD diamond material. The second layer of polycrystalline diamond layer may be grown to a thickness equal to or greater than: 25 μm; 50 μm; 75 μm; 100 μm; 200 μm; 300 μm; or 400 μm and optionally equal to or less than: 1 mm; 750 μm; 500 μm; 400 μm; or 300 μm. The two layers of CVD diamond material may be distinguishable in the final substrate structure. For example, an interface between the two layers may be discernible by the presence of a layer of defects indicating that CVD growth has been performed in two steps. Furthermore, the two layers of CVD diamond material may be grown under different synthesis conditions and thus have different characteristics such as different thermal conductivities. In such circumstances, it may be advantageous for the first layer of CVD diamond material to have a higher thermal conductivity than the second layer of CVD diamond material as the first layer will be located closest to active compound semiconductor components of the end device. For example, the first layer of diamond material may have a thermal conductivity equal to or greater than 600 Wm⁻¹K⁻¹, 800 Wm⁻¹K⁻¹, 1000 Wm⁻¹K⁻¹, 1200 Wm⁻¹K⁻¹, or 1400 Wm⁻¹K⁻¹. Such high quality polycrystalline diamond material can be fabricated using a microwave plasma method as opposed to a hot filament method. Accordingly, it may be advantageous to fabricate one or both layers of polycrystalline diamond material by a microwave plasma method.

Any one of a number of methods may be used to process the substrate wafer back to the first layer of single crystal diamond material after CVD diamond growth thereon. Suitable methods include: wet etching; dry etching; plasma etching; electrochemical etching; lapping; and cleaving. However, it has been found that wet etching is particularly suited for use in combination with the substrate wafer structures described herein as this method is compatible with the inclusion of a crack-stop layer which can also function as an etch stop. Furthermore, etching can produce a uniformly thick layer of single crystal material even if the composite wafer structure is slightly bowed. Further still, etching can avoid the possibility of mechanically introducing damage into the thin layer of single crystal material. For example, a chemical etchant may be used to selectively etch away the handling wafer. If the handle wafer is formed of silicon material whereas the crack-stop layer if formed of SiO2, then a suitable etchant can be selected to etch the handling wafer without etching the crack-stop layer. An example of such an etchant is EDP (an aqueous solution of ethylene diamine and pyrocatechol). The SiO₂ layer can then be removed using an etchant which preferentially etches the SiO₂ without etching the thin layer of single crystal silicon material adjacent the polycrystalline diamond layer. An HF acid etchant is suitable for this purpose.

In one arrangement, an anisotropic etchant can be selected which can etch the handling wafer at a considerably faster rate that the first layer of single crystal material adjacent the polycrystalline CVD diamond. Such an etchant can avoid undue edge etching of the first layer of single crystal material during removal of the handling wafer. In this regard, etching of major faces of the first layer is prevented by the presence of the polycrystalline CVD diamond and crack-stop layers. However, these layers do not prevent etching of the first layer of single crystal material at exposed edge regions. As such, application of an anisotropic etch has been found to be advantageous. For example, KOH solution etches a {100} oriented silicon handling wafer (i.e. a silicon handling wafer having {100} major faces) approximately 400 times faster than a silicon layer having {111} oriented major faces adjacent the polycrystalline CVD diamond layer. Accordingly, if {111} oriented silicon is used for the thin layer of material adjacent the polycrystalline CVD diamond and {100} oriented silicon is used for the handling wafer, then an anisotropic etch can be applied such that the handling wafer is removed without significantly etching away the edges of the {111} oriented silicon adjacent the polycrystalline CVD diamond.

Alternatively, the above described problem of edge etching can be solved by providing an etch stop around the edges of the first layer of single crystal material. For example, one advantageous method involves overgrowing the CVD diamond material around the sides of the substrate wafer such that edge grown CVD diamond material masks the edges of the first layer of single crystal material and functions as an etch stop during subsequent processing of the substrate wafer.

Alternatively still, the above described problem of edge etching can be solved by heavily doping the handling wafer such that it is electrically conductive while providing a first layer of single crystal material which has a high electrical resistivity. The conductive handling substrate can then be removed by electrochemical etching without removal of the electrically resistive first layer of material.

Using the above described methodology it is possible to fabricate a composite substrate comprising a layer of polycrystalline CVD diamond material with a thin, high quality, relatively crack free, layer of single crystal material directly bonded thereto which is suitable for epitaxial growth of a highly quality compound semiconductor. For example, the layer of single crystal material may be substantially crack free over at least a central region thereof, wherein the central region is at least 50%, 60% 70%, 80%, 90%, or 95% of a total area of layer of single crystal material, and wherein the central region has no cracks which extend greater than 2 mm in length.

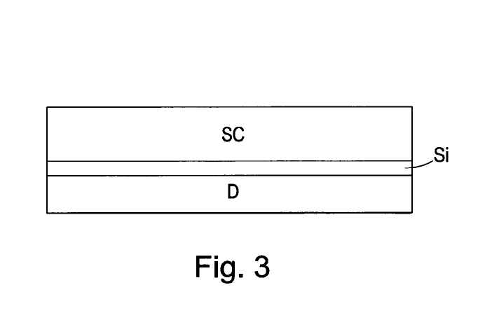

A better performance semiconductor device can be fabricated using such a composite substrate due to the improved nature of the growth surface while at the same time providing good thermal contact between the active device layers and the polycrystalline CVD diamond by locating the two very close together. An example of a portion of such a device structure is illustrated in FIG. 3 which illustrates a layer structure comprising a polycrystalline CVD diamond substrate D, a thin layer of single crystal silicon Si, and a layer of single crystal compound semiconductor SC, such as a nitride compound semiconductor comprising alloys of gallium and/or aluminium and/or indium and nitrogen, epitaxially grown over the thin layer of single crystal silicon.

The layer of single crystal compound semiconductor may have a charge mobility no less than 1000 cm²V⁻¹s⁻¹, 1200 cm²V⁻¹s⁻¹, 1400 cm²V⁻¹s⁻¹, 1600 cm²V⁻¹s⁻¹, 1800 cm²V⁻¹s⁻¹, or 2000 cm²V⁻¹s⁻¹. While such charge mobilities of compound semiconductor layers have previously been achieved on non-diamond substrates and may be achieved on diamond substrates when the semiconductor layer is not in good thermal contact with the diamond substrate layer, the combination of a relatively thick, high thermal conductivity diamond layer in combination with a high quality, low strain compound semiconductor layer, with both layers disposed in very close proximity to provide good thermal contact has proved difficult to date for the reasons explained in this specification.

While this invention has been particularly shown and described with reference to preferred embodiments, it will be understood to those skilled in the art that various changes in form and detail may be made without departing from the scope of the invention as defined by the appendant claims.

The work leading to this invention has received funding from the [European Community's] [European Atomic Energy Community's] Seventh Framework Programme ([FP7/2007-2013] [FP7/2007-2011]) under grant agreement n° [214610].

1. A method of manufacturing a composite substrate for a semiconductor device, the method comprising:
selecting a substrate wafer comprising: a first layer of single crystal material suitable for epitaxial growth of a compound semiconductor thereon and having a thickness of 100 μm or less; a second layer having a thickness of no less than 0.5 μm and formed of a material having a lower thermal expansion coefficient than the first layer of single crystal material and/or is formed of a material which has a higher fracture strength than that of the first layer of single crystal material; and a third layer forming a handling wafer on which the first and second layers are disposed, wherein the substrate wafer has an aspect ratio, defined by a ratio of thickness to width, of no less than 0.25/100;
growing a first polycrystalline CVD diamond layer on the first layer of single crystal material using a chemical vapour deposition technique to form a composite comprising the substrate wafer bonded to the polycrystalline diamond layer via the first layer of single crystal material, wherein during growth of the first polycrystalline CVD diamond layer a temperature difference at a growth surface between an edge and a centre point thereof is maintained to be no more than 80° C.; and
removing the second and third layers of the substrate wafer to form a composite substrate comprising the polycrystalline diamond layer directly bonded to the first layer of single crystal material.

2. A method according to claim 1, wherein the first layer of single crystal material has a thickness of: 75 μm or less; 50 μm or less; 30 μm or less; 20 μm or less; 10 μm or less; 5 μm or less; 3 μm or less; 2 μm or less; or 1 μm or less.

3. A method according to claim 1, wherein the first layer of single crystal material has a thickness greater than 10 nm, 20 nm, 50 nm, 100 nm, 200 nm, or 500 nm.

4. A method according to claim 1, wherein the first layer of single crystal material is formed of silicon, silicon carbide, or a nitride.

5. A method according to claim 1, wherein the first layer of single crystal material is formed of {111} oriented silicon.

6. A method according to claim 1, wherein the second layer of material has a thickness of: 0.75 μm or more; 1.0 μm or more; 2 μm or more; or 4 μm or more.

7. A method according to claim 1, wherein the second layer of material has a thickness of: 10 μm or less; or 5 μm or less.

8. A method according to claim 1, wherein the second layer of material is formed of a material having a lower thermal expansion coefficient than the CVD synthetic diamond material.

9. A method according to claim 1, wherein the second layer of material is formed of an amorphous material.

10. A method according to claim 1, wherein the second layer of material is formed of SiO₂.

11. A method according to claim 1, wherein the third layer has a thickness in a range: 0.3 mm to 2.0 mm; 0.3 mm to 1.8 mm; 0.3 mm to 1.5 mm; 0.3 mm to 1.3 mm; 0.3 mm to 1.0 mm; or 0.5 mm to 0.8 mm.

12. A method according to claim 1, wherein the third layer is formed of silicon, silicon carbide, or a nitride.

13. A method according to claim 1, wherein the third layer is formed of {100} oriented silicon.

14. A method according to claim 1, wherein the material of the third layer has a thermal expansion coefficient larger than the material of the second layer.

15. A method according to claim 1, wherein the material of the third layer has an electrical resistivity lower than the material of the first layer.

16. A method according to claim 1, wherein the material of the third layer has a different crystallographic orientation to the material of the first layer.

17. A method according to claim 1, wherein the aspect ratio of the substrate wafer is no less than 0.30/100, 0.40/100, 0.50/100, 0.60/100, 0.70/100, 0.80/100, 0.90/100, or 1.0/100.

18. A method according to claim 1, wherein the temperature difference between the edge and centre point of the growth surface is maintained to be no more than 60° C., 40° C., 20° C., 10° C., 5° C., or 1° C.

19. A method according to claim 1, wherein the substrate wafer has a diameter in a range: 20 mm to 300 mm; 20 mm to 250 mm; 20 mm to 200 mm; 20 mm to 160 mm; 40 mm to 140 mm; 60 mm to 120 mm; 80 mm to 120 mm; or 90 mm to 110 mm.

20. A method according to claim 1, wherein the first layer of polycrystalline diamond layer is grown to a thickness in the range: 25 μm to 150 μm 50 μm to 130 μm; 70 μm to 130 μm; 80 μm to 120 μm, or 90 μm to 110 μm.

21. A method according to claim 1, wherein removal of the second layer, and if present the third layer, of the substrate wafer is achieved by one or more of: wet etching; dry etching; plasma etching;
electrochemical etching; and lapping.

22. A method according to claim 1, wherein after removing the carrier layer a second layer of polycrystalline diamond is grown over the first layer of polycrystalline diamond material.

23. A method according to claim 22, wherein the second layer of polycrystalline diamond layer is grown to a thickness equal to or greater than: 25 μm; 50 μm; 75 μm; 100 μm; 200 μm; 300 μm; or 400 μm.

24. A method according to claim 22, wherein the second layer of polycrystalline diamond layer is grown to a thickness equal to or less than: 1 mm; 750 μm; 500 μm; 400 μm; or 300 μm.

25. A method according to claim 1, wherein the first layer of diamond material has a thermal conductivity equal to or greater than 600 Wm⁻¹K⁻¹, 800 Wm⁻¹K⁻¹, 1000 Wm⁻¹K⁻¹, 1200 Wm⁻¹K⁻¹, or 1400 Wm⁻¹K⁻¹.

26. A method according to claim 1, wherein the first layer of diamond material, and if present the second layer of polycrystalline diamond material, is fabricated by a microwave plasma method.

27. A composite substrate for a semiconductor device, the composite substrate comprising:
a layer of polycrystalline diamond; and
a layer of single crystal material suitable for epitaxial growth of a compound semiconductor,
wherein the layer of single crystal material is directly bonded to the layer of polycrystalline diamond and has a thickness of 100 μm or less,
wherein the layer of single crystal material is substantially crack free over at least a central region thereof, wherein the central region is at least 50%, 60% 70%, 80%, 90%, or 95% of a total area of layer of single crystal material, and wherein the central region has no cracks which extend greater than 2 mm in length.

28. A composite structure according to claim 27, wherein the width of the composite structure is no less than 50 mm, 70 mm, 90 mm, 110 mm, 130 mm, 150 mm, 170 mm, 190 mm, 210 mm, 230 mm, 250 mm, 300 mm, 400 mm, or 500 mm and the aforementioned thermal conductivity and charge mobility limitations apply over at least a central portion of the composite structure, wherein the central portion is at least 50%, 60%, 70%, 80%, 90%, or 95% of a total area of the composite structure.

29. A method of manufacturing a semiconductor device comprising:
providing the composite substrate as claimed in claim 27; and
epitaxially growing a layer of single crystal compound semiconductor material over the layer of single crystal material.

30. A semiconductor device comprising:
the composite substrate as claimed in claim 27; and
a layer of single crystal compound semiconductor material epitaxially grown over the layer of single crystal material,
wherein the layer of single crystal compound semiconductor material has a charge mobility no less than 1000 cm²V⁻¹s⁻¹, 1200 cm²V⁻¹s⁻¹, 1400 cm²V⁻s⁻¹, 1600 cm²V⁻¹s⁻¹, 1800 cm²V⁻¹s⁻¹, or 2000 cm²V⁻s⁻¹.
